(19) United States
(12) Patent Application Publication
(10) Pub. No.: US 2024/0072515 A1
(43) Pub. Date: Feb. 29, 2024

(54) ROOM TEMPERATURE LASING FROM SEMICONDUCTING SINGLE WALLED CARBON NANOTUBES

(71) Applicants: UCHICAGO ARGONNE, LLC, Chicago, IL (US); NORTHWESTERN UNIVERSITY, Evanston, IL (US)

(72) Inventors: Xuedan Ma, Woodridge, IL (US); Jia-Shiang Chen, Downers Grove, IL (US); Mark Hersam, Evanston, IL (US); Anushka Dasgupta, Evanston, IL (US)

(21) Appl. No.: 17/894,009

(22) Filed: Aug. 23, 2022

(51) Int. Cl. H01S 5/068; H01S 5/024; H01S 5/10; H01S 5/20

(52) U.S. Cl. CPC H01S 5/06804; H01S 5/02407; H01S 5/1067; H01S 5/204

(57) ABSTRACT

Optical gain media and gain devices are required for lasing devices and high intensity optical systems across a wide range of application. A compact optical gain device that provides near-infrared and infrared lasing at room temperature includes an optical microcavity having a refractive index and a curvilinear outer surface with an angle of curvature such that the optical microcavity supports the propagation of an electromagnetic whispering gallery mode. A plurality of optical gain structures are disposed along the curvilinear outer surface of the optical microcavity, the each of the optical gain structures having an optically active wavelength range over which each of the corresponding optical gain structures provides optical gain to radiation through stimulated emission.

### STATEMENT REGARDING FEDERALLY SPONSORED RESEARCH OR DEVELOPMENT

This invention was made with government support under Contract No. DE-AC02-06CH11357 awarded by the United States Department of Energy to UChicago Argonne, LLC, operator of Argonne National Laboratory. The government has certain rights in the invention.

### FIELD OF THE DISCLOSURE

The present disclosure relates to methods and systems for performing optical gain, and specifically to generating optical gain in whispering gallery modes at room temperature.

### BACKGROUND

Laser media and devices are valuable, and even required, across a wide range of industries. Specifically, laser devices that operate in the near infrared and infrared ranges are technologically valuable in communications, medicine, biomedical imaging, research, quantum information technologies, and part manufacturing, among other fields of endeavor. Lasing devices require specific physical conditions to operate. For example, a lasing device must achieve an amount of stimulated emission that exceeds a lasing threshold of the device to operate as a laser. One physical element that contributes to proper operation of a laser is the gain medium of the laser. The gain medium is a material having properties that allow for amplification of light through stimulated emission. The gain medium may be a gas, a fluid, or a solid material that can absorb energy, and emit light. Another critical element for lasing is a resonant cavity in which radiation may contain the propagation of radiation to stimulate emission in the gain medium. The operating wavelengths of a lasing device depend on both the gain medium and geometries of the resonant cavity of the device. For example, a neodymium-doped yttrium aluminum garnet (Nd: YAG) laser operates at visible wavelengths, while a CO₂ laser operates in the microwave regime and a titanium-doped sapphire (Ti:Al₂O₃) laser emits red and near-infrared light. While YAG, CO₂, and Ti:Al₂O₃ lasers are established technologies, the lasers are extremely bulky due to the lengths of required lasing cavities and other required optical elements. Further, many of these types of lasers are not viable for biological research of systems due to the required sizes and/or chemicals not being biocompatible.

Laser devices that operate in near infrared wavelengths are particularly valuable for communications and biological applications. Most laser mediums that operate in the near infrared use rigid semiconductor materials as the gain medium. Semiconductor-based devices are typically not readily scalable due to material limitations, and miniaturization of semiconductor lasers is limited. For example, VCSEL diode lasers may provide some radiation in the near infrared band, but are too large in form factor to integrate into many systems for biological applications or on-chip optical processing. Further, semiconductor devices are limited in lasing wavelength ranges due to the emission energies achievable in semiconductor materials.

Wavelength tunability of a typical semiconductor device is also very limited as the rigid structures of semiconductor materials create challenges in tuning thicknesses and purities of materials at scales of nanometer and tens of nanometers. Additionally, many lasing devices require cooling mechanisms to control the temperature of the gain medium. Changes in gain medium temperature cause wavelength drift, which may change hour to hour, or minute to minute based on the type of laser and the environment in which the laser is deployed. Temperature changes may also cause a device to stop lasing altogether due to changes in material properties or cavity dimensions.

Due to the broad range of uses of lasing devices, there is need for lasing devices that utilize gain mediums that may be fabricated to operate across various bands of wavelengths, using materials and methods that are biocompatible, allow for miniaturization, and allow for implementation in a variety of form factors at room temperature environments.

### SUMMARY OF THE DISCLOSURE

In an embodiment, disclosed is an optical gain device including an optical microcavity and a plurality of optical gain structures. The optical microcavity has a refractive index and curvilinear outer surface with an angle of curvature such that the optical cavity supports the propagation of an electromagnetic whispering gallery mode. The plurality of optical gain structures is disposed along the curvilinear surface of the optical microcavity. Each of the optical gain structures has an optically active wavelength range over which each of the corresponding optical gain structures provides optical gain to radiation through stimulated emission. In variations of the current embodiment, the optical microcavity is a microsphere. Additionally, in variations of the current embodiment the plurality of optical gain structures includes a single-walled carbon nanotube.

In another embodiment, disclosed is a method of fabrication. The method includes fabricating a plurality of optical gain devices having an optical microcavity and optical gain structures as disclosed in the previous embodiment. The method includes providing a plurality of optical microcavities to a solution, and providing a plurality of optical gain structures to the solution. The method then includes causing swelling of the plurality of optical microcavities to increase at least one spatial dimension of the optical microcavities while in the presence of the optical gain structures. De-swelling of the optical microcavities is then caused to reduce the at least one spatial dimension of the optical microcavities to adsorb at least a portion of the optical gain structures to the outer surface of the optical microcavities. In variations of the current embodiment, the optical microcavities include microspheres. Additionally, in variations of the current embodiment, the optical gain structures include single-walled carbon nanotubes.

### BRIEF DESCRIPTION OF THE DRAWINGS

FIG. 1 is a block diagram of a laser device having a pump source, gain medium, and radiation cavity.

FIG. 2A is a diagram illustrating an electron in the ground state in a three-state quantum well system.

FIG. 2B is a diagram illustrating radiation exciting an electron from the ground state to a second excited state in a three-state quantum well system.

FIG. 2C is a diagram illustrating emission of a photon and relaxation of an electron from a second excited state to a first excited state in a three-state quantum well system.

FIG. 2D is a diagram illustrating emission of a photon and relaxation of an electron from a first excited state to a ground state in a three-state quantum well system.

FIG. 2E is a diagram illustrating an electron at ground state in a multi-state quantum well system for performing stimulated emission.

FIG. 2F is a diagram illustrating radiation exciting an electron from the ground state to a second excited state in a multi-state quantum well system.

FIG. 2G is a diagram illustrating emission of a photon and relaxation of an electron from a second excited state to an intermediate excited state in a multi-state quantum well system.

FIG. 2H is a diagram illustrating emission of a photon and relaxation of an electron from a first excited state to a ground state through stimulated emission in a multi-state quantum well system.

FIG. 3A is a diagram illustrating Snell's law and total internal reflection.

FIG. 3B is a ray diagram illustrating a whispering gallery mode propagating inside of a circular medium through total internal reflection.

FIG. 3C is a simulated image of an electromagnetic wave propagating in a whispering gallery mode around a circular medium.

FIG. 4A is a diagram of an optical gain device having a circular cavity medium with a boundary along which radiation propagates as a whispering gallery mode.

FIG. 4B is an optical micrograph image of an optical gain device with a polystyrene (PS) microsphere spin coated onto a cover glass.

FIG. 4C is a zoomed in optical micrograph image of FIG. 4B showing an outer surface of the PS microsphere.

FIG. 5 is a flow diagram of a method for fabricating a plurality of optical gain devices.

FIG. 6 is a flow diagram illustrative of the method of FIG. 5.

FIG. 7 is a microscopy image of a plurality of PS microspheres 702 used to fabricate optical gain devices as described herein.

FIG. 8A is a microscopy image of a PS microsphere spin-coated onto coverglass.

FIG. 8B is a zoomed in image of an outer surface of the microsphere of FIG. 8A.

FIG. 8C is a zoomed in image of the outer surface of the microsphere of FIG. 8B.

FIG. 9A is a microscopy image of an optical gain device having a microsphere and optical gain structures adsorbed to an outer surface of the microsphere.

FIG. 9B is a zoomed in image of the outer surface and adsorbed optical gain structures of the optical gain device of FIG. 9A.

FIG. 9C is a zoomed in image of the outer surface and adsorbed optical gain structures of the optical gain device of FIG. 9B.

FIG. 10A is a simulated image of a transverse-magnetic whispering gallery mode propagating in a microsphere having a five micron diameter.

FIG. 10B is a plot of transverse-magnetic whispering gallery mode wavelength spectra supported by the microsphere of FIG. 10A.

FIG. 10C is a simulated image of a transverse-electric whispering gallery mode propagating in a microsphere having a five micron diameter.

FIG. 10D is a plot of transverse-electric whispering gallery mode wavelength spectra supported by the microsphere of FIG. 100.

FIG. 10E is a simulated image of a transverse-electric whispering gallery mode propagating in a microsphere having a seven micron diameter.

FIG. 10F is a plot of transverse-electric whispering gallery mode wavelength spectra supported by the microsphere of FIG. 10E.

FIG. 10G is a simulated image of a transverse-magnetic whispering gallery mode propagating in a microsphere having a seven micron diameter.

FIG. 10H is a plot of transverse-magnetic whispering gallery mode wavelength spectra supported by the microsphere of FIG. 10G.

FIG. 11 is a histogram of experimentally measured quality factors for a plurality of optical gain devices that employ PS microspheres and single walled carbon nanotubes (SWCNTs).

FIG. 12 is a histogram of beta factor values for a plurality of optical gain devices.

FIG. 13A is a plot of output laser radiation intensity versus input pump power for an optical gain device having a beta factor of 0.11.

FIG. 13B is a plot of output laser radiation intensity versus input pump power for an optical gain device having a beta factor of 0.05.

FIG. 13C is a plot of the spectrum of the output laser radiation from an optical gain device having a beta factor of 0.11.

FIG. 13D is a plot of the spectrum of the output laser radiation from an optical gain device having a beta factor of 0.05.

FIG. 13E is a plot of pump excitation wavelength vs. emission wavelength for unfunctionalized SWCNTs.

FIG. 13F is a plot of pump excitation wavelength vs. emission wavelength for functionalized SWCNTs.

FIG. 14 is a plot of output laser radiation intensity over time for an optical gain device employing a PS microsphere as a cavity and SWCNT as a gain structure.

FIG. 15 is a plot of peak wavelength output versus applied pump power.

FIG. 16 is a plot of output laser radiation intensity spectra for different pump powers.

FIG. 17 shows two plots of normalized output photon count at pump powers greater than (top), and less than (bottom) the lasing threshold power for an optical gain device.

FIG. 18 is a plot of output lasing spectra for optical gain devices having different microsphere diameters and different SWCNT chemical modifications.

FIG. 19 is a block diagram illustrating an example of an optical processing system having an on-chip lasing device.

FIG. 20 is a diagram of a lasing medium that includes a plurality of optical gain devices disposed in a fluid solution.

### DETAILED DESCRIPTION

Laser devices are valuable across a wide range of industries from medical devices to defense and communication systems. As such, each application that uses a laser may require different types of radiation, different output radiation parameters (e.g., pulsed or continuous operation, polarizations, etc.), operational environments, or other conditions of operation for a given application. For example, some systems may require a laser to output radiation at visible wavelengths, while another application may require laser radiation at infrared wavelengths. Additionally, lasers may be required to be employed in different environments including very humid or wet environments, dry environments, integrated on-chip, in biological tissue, or environments under extreme heat or pressure, just to name a few. As such, the specific materials and form factors of laser devices are important for meeting the requirements of each individual application and environment for employing a laser device. Many laser systems are too bulky to be useful for multiple applications and in various environments.

The disclosed lasing devices employ microspheres which support whispering gallery modes to act as lasing cavities. Gain medium structures are dispersed along the path of propagation of the radiation in the whispering gallery modes. Utilizing microscopic structures to host the whispering gallery modes allows for miniaturization of lasing devices, which, in turn, allows for more robust laser design including the ability to integrate a laser on-chip for optical processing and computing, and provide the optical gain medium to a solution for performing lasing in a variety of chemical applications. The proposed lasing medium can operate at room temperature, and is fabricated using biocompatible materials allowing for deployment of the lasing materials in tissue for a wide array of biological applications.

In electromagnetics, it is common to distinguish between a frequency, wavelength, energy, and color of electromagnetic radiation. Each of these four characteristics is related to the other three. For example, the wavelength, in nanometers (nm), and frequency, in hertz (Hz), for a specified electromagnetic radiation are inversely proportional to each other. Similarly, the energy, in electron-volts (eV) or joules (J), of electromagnetic radiation is proportional to the frequency of that radiation. Therefore, for a given radiation at a given frequency, there is a corresponding wavelength and energy. The color of a photon or electromagnetic radiation typically represents a group of band of frequencies, or a frequency shift of light (i.e., blue-shift means decreasing in wavelength while red-shift means increasing in wavelength.) Some areas of trade in electromagnetics prefer the use of one of the four terms over the others (e.g., color and wavelength are preferred when discussing optical filters, whereas frequency and energy are preferred when optical excitation processes). Therefore, the four terms may be understood to be freely interchangeable as appropriate, in the following discussion of electromagnetic radiation, photons, quantum states, electrons, and radiation sources.

Additionally, as a person of ordinary skill in the art would understand, the terms excited state, excitation state, quantum state, and energy state can be interchangeable when describing the state of a system. Also, the states of a system may also be described as having or existing with a specific energy, E, associated with the state. Therefore, it should be understood that a state may be referred to as an energy state E, or a state with energy E interchangeably. As such, it should be understood that a label E may refer to the energy of a state and/or to the state itself. In addition, a person of ordinary skill in the art would recognize that the terms excite, promote, or energize are often interchangeable when discussing the transition of a system from one energy level to another, higher, energy level, and similarly the terms de-excite, relax, and recombine may be used interchangeably when discussing the transition of a system from one energy level to another, lower, energy level.

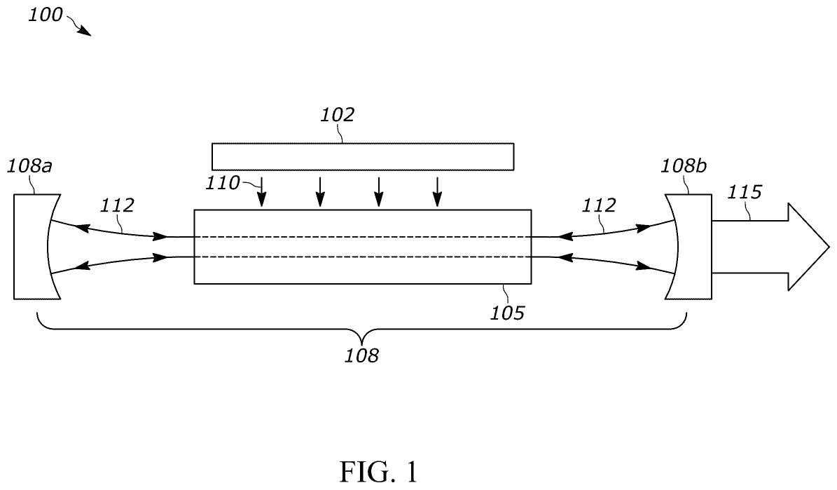

FIG. 1 is a block diagram of a typical laser device 100 having a pump source 102, a gain medium 105, and a radiation cavity 108. The pump source 102 provides pump radiation 110 to the gain medium 105 to provide energy to the gain medium 105. The pump radiation 110 has a frequency corresponding to an excitation energy of the gain medium 105, and the pump radiation 110 excites electrons of the gain medium 105 to an excited state. The electrons then decay back to a lower energy state and emit radiation 112 into the radiation cavity 108. The radiation cavity 108 includes two mirrors, a back mirror 108a that is highly reflective, (i.e., approximately 100% reflective for the wavelength of the radiation 112), and a front mirror 108b that is partially transmissive at the wavelength of the radiation 112. The mirrors 108a and 108b provide optical feedback to the gain medium causing stimulated emission of more photons having a same wavelength as the radiation 112, and further causing emission of coherent radiation. The front mirror 108b transmits a portion of the radiation 112 as output radiation 115. The output radiation 115 is coherent radiation at a wavelength determined by the properties of the gain medium 105 and the radiation cavity 108, as further discussed herein.

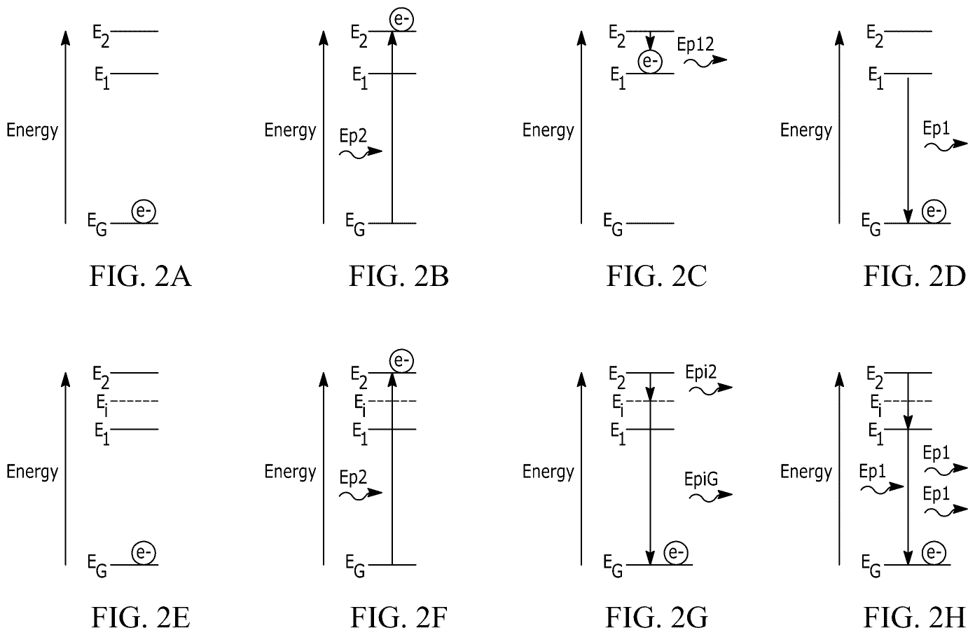

FIGS. 2A-2D show an electron, e-, in a quantum well semiconductor material being a nanomaterial, and three energy states: a ground energy state, E_{G}, a primary excited energy state, E₁, and a secondary excited energy state, E₂. The ground state E_{G} may be a valence band state (e.g., a heavy-hole, light-hole, or spin-orbit band or state). The energy band diagram of FIGS. 2A-2D may be representative of energy bands of a nanoparticle or nanostructure such as a quantum dot, nanotube, nanorod, nanocluster, nanopowder, nanocrystal, or nanoplate or another structure exhibiting a quantum well or quantum fountain energy band structure. In FIGS. 2A-2D, the primary excited energy state is the lowest excited state or first excited energy state with energy E₁, and the secondary excited energy state is a second excited energy state with an energy E₂, greater than E₁ with both the primary and secondary bands being in the conduction band. As illustrated in FIG. 2B the electron typically exists in or occupies the ground energy state. The electron remains in the ground energy state until some form of excitation or perturbation changes the state of the electron in the quantum well. FIG. 2B illustrates an excitation energy provided by a photon with energy Eₚ₂. The photon provides energy to the electron exciting it to the second excited state, E₂. The energy gap between the ground state and the primary and secondary excited states may be determined by the material properties and dimensions of the physical structure of the quantum well (i.e., structural geometries of the quantum dot, nanorod, etc.). Once in the secondary excited state, the electron may couple to vibrational modes, de-excite or relax down into the primary excited state, and emit phonons, or the electron may relax into the primary excited state and emit a photon with energy E₁₂, as illustrated in FIG. 2C. Once in the primary excited state, the electron may further relax back into the ground state and emit phonons, or emit a photon with energy Eₚ₁, as illustrated in FIG. 2D. FIGS. 2A-2D illustrate the process of spontaneous emission of a photon from a quantum well. Specifically, spontaneous emission of the photon having energy Eₚ₁ occurs after exciting of the electron from the ground state to the secondary excited state.

For lasing application, a build-up of photons is required to cross a lasing threshold to cause a population inversion in a gain material. Therefore, to continue to increase the number of coherent photons in a cavity or material, gain can be achieved through the process of stimulated emission of photons. FIGS. 2E-2H illustrate the process of stimulated emission of photons for achieving lasing in a gain medium. The system of FIGS. 2E-2H further includes a band of intermediate energy levels having energy Eᵢ, with the intermediate level energies being anywhere between the primary and secondary energy levels. The intermediate energy levels may also exist in the system of FIGS. 2A-2D but were omitted for simplicity and clarity. As described previously, and again illustrated in FIG. 2E, the electron initially exists in the ground state at E_{G}. A pump photon having energy Eₚ₂ then promotes the electron to the secondary energy state, as illustrated in FIG. 2F. As previously described, spontaneous emission of a photon may then occur, but the spontaneous emission may not result in the emission of a photon having energy Eₚ₁ as previously described. FIG. 2G illustrates spontaneous emission of a photon with the electron first de-exciting to one of the intermediate states, and then further de-exciting to the ground state. This results in the emission of a photon having energy E_{iG} instead of a photon having energy Eₚ₁. As such, the photons emitted from the system may have any energies determined by the various transitions from the secondary excited state, to the ground state, through any of the intermediate states. Additionally, spontaneously emitted photons are emitted isotopically and are not readily coupled to a resonant cavity. Therefore, spontaneous emission of radiation does not readily enable lasing due to the randomness of the wavelengths, energies, and phases of spontaneously emitted photons.

FIG. 2H illustrates an example of stimulated emission of a photon. Instead of de-excitation via spontaneous emission, as shown in FIG. 2G, a seed photon having energy Eₚ₁ is provided to the system, which stimulates the electron to emit a photon having the same energy Eₚ₁ resulting in the co-propagation of two photons having same energy Eₚ₁. As such, the electron is forced to de-excite to the energy E₁ either through the path shown in FIG. 2H, or through intermediate states, and then de-excited from Eₚ₁ to the ground state. Not only does the newly emitted photon have a same energy as the seed photon, but the newly emitted photon has a same phase and propagation direction as the seed photon. Therefore, stimulated emission of photons allows for optical gain in an optical cavity having a gain medium due to the coherent nature of the process of stimulated emission. As described herein, lasing is achieved by first causing spontaneous emission of photons and coupling a portion of the spontaneously emitted photons into an optical cavity. The spontaneously emitted photons then act as seed photons for stimulated emission resulting in lasing.

As described with reference to FIG. 1, an optical cavity is required to provide feedback in a gain medium to achieve lasing. While the radiation cavity 108 of FIG. 1 employs two mirrors surrounding the gain medium 105, the disclosed optical gain devices utilize electromagnetic whispering gallery modes to provide optical feedback to a gain medium to achieve optical gain. Whispering gallery modes, also referred to as whispering gallery waves, are electromagnetic waves guided by a curved surface of an object or curved boundary. The electromagnetic waves are guided through total internal reflection as described by Snell's law.

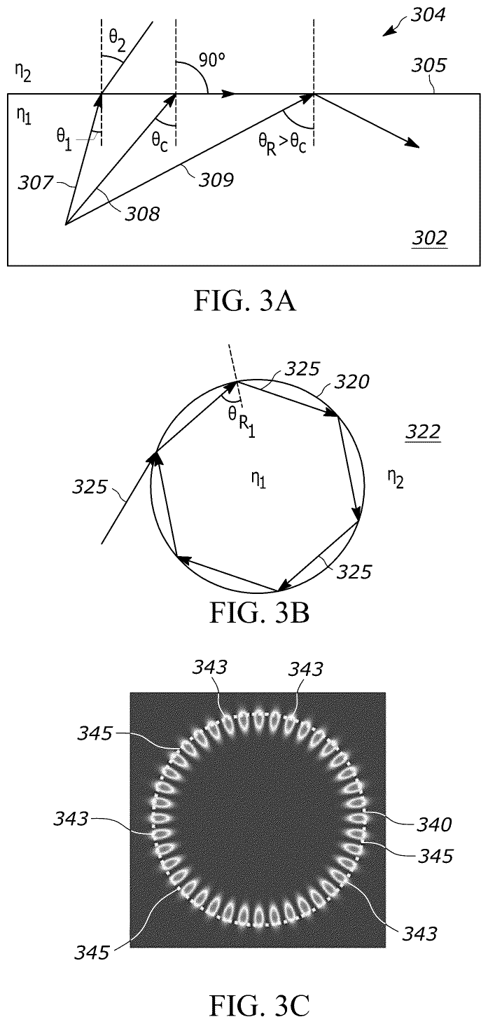

The disclosed optical gain devices use total internal refraction and whispering gallery mode propagation in an optical cavity to cause lasing. FIG. 3A is a diagram illustrating Snell's law and total internal reflection. Snell's law describes the relationship between angles of incidence, and angles of reflection for rays of electromagnetic radiation. As shown with reference to ray 307 of FIG. 3, Snell's law is given as

$$\frac{sin {θ}_{1}}{sin {θ}_{2}} = \frac{{n}_{2}}{{n}_{1}} , \qquad EQ . 1$$

with θ₁ being the angle of incidence between the incident ray 307 and the normal line that is perpendicular to the interface between the two media, θ₂ being the refracted angle of the ray 307, n₁ being a refractive index of a first medium 302, and n₂ a refractive index of a second medium 304. Snell's law allows one to determine the various angles of incidence, and angles of refraction from the indices of refraction of two materials being traversed by a ray of light. As illustrated in FIG. 3A, the ray 307 passes from the first medium 302 to the second medium 304 and is refracted at the boundary 305. A critical angle θ_{C} exists between the two mediums 302 and 304 at which light does not pass through the boundary. For example, a second ray 308 is incident on the second medium 304 at the critical angle θ_{C} and the second ray 308 continues to propagate in the first medium 302 parallel to the boundary 305. In this scenario θ₂=90°, and Snell's law can be simplified to

$$\frac{sin {θ}_{1}}{sin ( 90 ° )} = \frac{sin {θ}_{1}}{1} = \frac{{n}_{2}}{{n}_{1}} , \qquad EQ . 2$$

and θ_{C} can then further be determined by

$${θ}_{C} = arcsin ( \frac{{n}_{2}}{{n}_{1}} ) . \qquad EQ . 3$$

Rays that are incident on the second medium 304 at angles greater than the critical angle, i.e. θ₁>θ_{C} are totally internally reflected back into the first medium 302. For example, a third ray 309 is incident on the second medium 302 at an angle θ_{R} that is greater than the critical angle. The third ray 309 is then totally internally reflected as illustrated in FIG. 3A.

FIG. 3B is a ray diagram illustrating a whispering gallery mode propagating inside of a circular medium 320 through total internal reflection. The circular medium 320 has a refractive index n₁ and the external medium 322, or external environment, has a refractive index n₂. A ray 325 enters the circular medium 320 on a left side of the circular medium 320 as illustrated. The ray 325 is then totally internally reflected in the circular medium 320. The ray 325 reflects at periodic distances and generates a spatial mode that continues to propagate around the circular medium 320. This phenomenon is known as the propagation of a whispering gallery wave, or a whispering gallery mode. The medium 320 behaves as a whispering gallery resonator, or optical cavity, and typically has a very high quality factor that depends on the lossiness of the cavity. For example, whispering gallery mode cavities may have quality factors greater than 10¹⁰. The high quality factors of whispering gallery modes result in the light being trapped in the cavity and propagating around the circular medium 320 for many cycles. The quality factor of a whispering gallery mode also depends on the wavelength of light propagating in the cavity, the refractive index of the circular medium 320, and the refractive index of the external medium or environment. The same three factors also determine the spatial modes and wavelengths of light that are supported by a given whispering gallery mode. FIG. 3C is a simulated image of an electromagnetic wave propagating in a whispering gallery mode around a circular medium 340. The image shows an oscillating field strength maximums 343 and minimums 345 as the wave propagates around the circular medium 340. FIGS. 3B and 3C demonstrate the same physical principal of whispering gallery modes by analyses under ray optics and wave optics respectively. While the ray optics approach describes the propagation of the radiation as passing through the circular medium 320 away from the surface or boundary of the medium, it should be understood that the radiation is actually guided along the boundary or surface of the circular medium as illustrated by the wave optics analysis illustrated in FIG. 3C. While illustrated as circular medium, the optical microcavity may be a sphere, torus, ellipse, or other geometric structure with a refractive index and curvilinear outer surface such that the optical microcavity supports the propagation of whispering gallery modes.

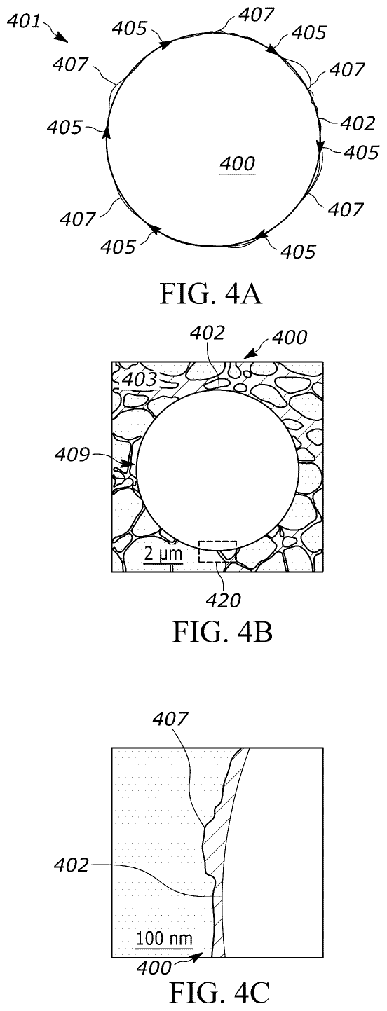

The disclosed optical gain devices utilize whispering gallery mode propagation in mediums as described above. The optical devices further include optical gain structures and materials along the path of the whispering gallery mode propagation along the surface or boundary of the optical gain device. FIG. 4A is a diagram of an optical gain device 400 with a circular medium 401 having a boundary 402 along which radiation 405 propagates as a whispering gallery mode. Gain structures 407 are disposed on the surface along the path of propagation of the whispering gallery mode radiation 405. The circular media 401 provide optical gain through stimulated emission of radiation as previously described. The gain provided by the circular media 401 continues to increase as more radiation is generated through stimulated emission. Some radiation is emitted from the circular medium 401 as loss. Eventually the intensity of the radiation 405 propagating in the whispering gallery mode reaches a threshold and the loss of radiation out of the cavity results in emitted laser light. As such, the circular medium 401 with gain structures 405 performs as an optical gain and lasing device.

While illustrated as propagating in a circular medium, it should be understood that whispering gallery modes may be supported and propagate in other geometric structures. For example, as further described herein, a spherical structure may support the propagation of whispering gallery modes. Further, whispering gallery modes may be formed in a planar circular medium (i.e., a flat circular disk shaped medium such as a coin shape), a torus, a sphere, an ellipse, a medium with a concave boundary, or another waveguide or medium having a curvilinear boundary or surface. Further, the mediums may be planar or three-dimensional structures having curvilinear boundaries. For simplicity and clarity, the disclosed optical gain devices will be described with reference to microspheres as the whispering gallery mode cavities.

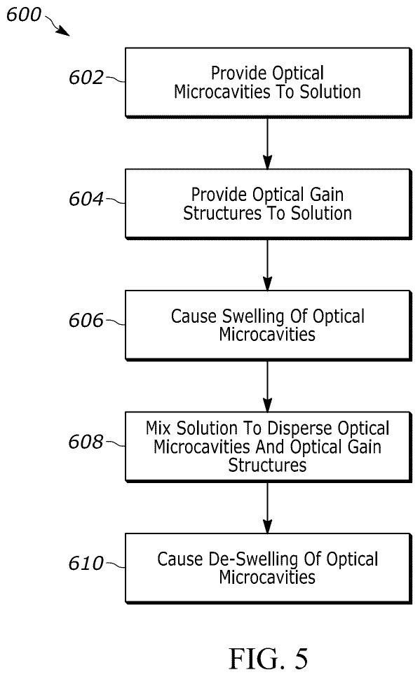

FIG. 4B is a transmission electron microscopy image, captured by a microscope, of an optical gain device 400 with a polystyrene (PS) microsphere 409 spin coated onto a TEM lacey carbon grid 403. The PS microsphere 409 adheres to the lacey carbon grid 403 to maintain a position of the PS microsphere 409 on the lacey carbon grid 403. The PS microsphere 409 has an outer surface 402 that is a curvilinear surface, and specifically, an outer convex surface with a radius of curvature on the order of microns. The PS microsphere 409 of FIG. 4B is one example of an optical microcavity for performing optical gain as described herein. While not visible in FIG. 4B, the PS microsphere 409 has gain structures adsorbed to the outer surface 402 of the PS microsphere 409. FIG. 4C is a zoomed-in optical micrograph image of a region 420 of FIG. 4B. FIG. 4C shows the outer surface 402 of the PS microsphere 409. FIG. 4C further shows an optical gain structure 407 adsorbed to the outer surface 402 of the PS microsphere 400. The optical gain structure 407 of FIG. 4C includes a plurality of nanotubes adsorbed to the outer surface 402. During operation, radiation may be injected into the PS microsphere 409 and causing one or more electromagnetic whispering gallery modes propagate along the outer surface 402. The whispering gallery modes spatially overlap with the nanotubes adsorbed to the outer surface 402, and the nanotubes provide optical gain to the radiation through stimulated emission, as described in reference to FIGS. 2E-2H, and further discussed in reference to FIG. 5. Loss of radiation from the microsphere 409 results in the release of laser radiation from the microsphere 409, which may then be coupled to waveguides or isotropically released.

Single walled carbon nanotubes (SWCNTs) are one example of a structure that may be employed as the optical gain structure as described herein. SWCNTs are nanoscale structures that are capable of providing optical gain in the NIR and IR wavelength ranges. Fabrication of SWCNTs is readily scalable, and therefore SWCNTs are readily accessible. SWCNTs are also compatible for integrating with other materials such as PS microspheres, semiconductor materials, and other engineered, incidental, and natural nanomaterials. SWCNTs are biocompatible and may be useful for providing optical gain in biological and medical applications. Existing systems and technologies have not achieved lasing using SWCNTs. For example, attempts at using cavity-induced Purcell effects to achieve optical gain with SWCNTs have been investigated, but cavity sizes and cavity losses prevent adequate optical gain to achieve lasing. As such, the described optical gain devices are the first demonstration of achieving lasing with SWCNTs as the optical gain medium.

The optical emission spectrum of SWCNTs is readily tunable through multiple physical and chemical properties. For example, tuning the diameter of a SWCNT changes an optically active wavelength range of the SWCNT. As used herein, an optically active wavelength range is a range of electromagnetic wavelengths at which an optical gain structure, such as a SWCNT, provides optical gain to radiation by emitting radiation through stimulated emission. The optically active wavelength range of a SWCNT may also be tuned by adding different functional groups to the SWCNT. For example, dichlorophenyl functional group may be attached to a SWCNT to tune the optically active wavelength range of the SWCNT. In fabrication, a precursor such as dichlorodiazonium may be used to facilitate the attachment of a functional group. The emission spectrum wavelength band increases with increased diameter of a SWCNT. Further, attached functional groups may provide a red shift of the emission spectrum wavelength band. The optically active wavelength range of a SWCNT may be tuned from around 1 microns, to 1.6 microns, spanning much of the NIR wavelength range. Controlling both the diameter of a SWCNT and any attached functional groups allows for the optically active wavelengths range of a SWCNT to be tuned from 800 nm to 1600 nm.

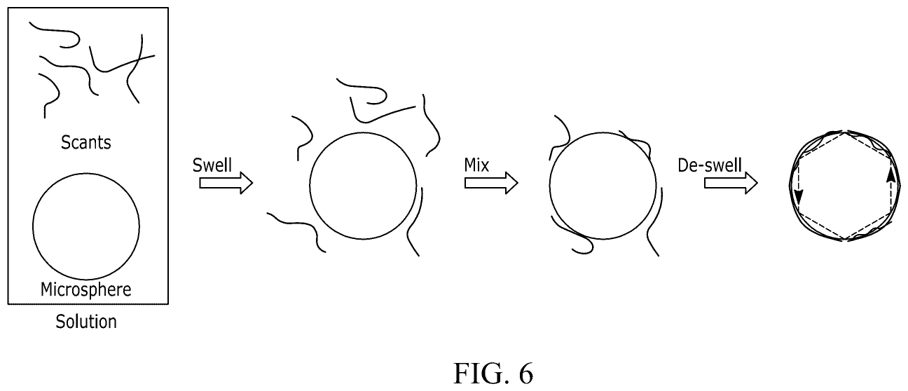

FIG. 5 is a flow diagram of a method 600 for fabricating a plurality of optical gain devices as described herein. FIG. 6 is a flow diagram illustrative of the method of FIG. 5. For clarity, the method 600 of FIG. 5 will be described with reference to elements of the optical gain device 400 of FIGS. 4A-4C. The method 600 includes providing a plurality of optical microcavities to a solution (block 602). The microcavities may be microspheres such as the microsphere 409 of FIG. 4B, or the microcavity may be a circular planar waveguide, a torus, a sphere, an ellipse, a medium with a concave boundary, or another waveguide or medium having a curvilinear boundary or surface. Further, the microcavities may be planar or three-dimensional structures having curvilinear boundaries. The solution may be a butanol or hexanol to facilitate fabrication of the optical gain devices. The solution may be contained in a cuvette, a glass vial, a glass scintillating vial, or another container that is not reactive to the solution.

The method 600 further includes providing optical gain structures 407 to the solution (block 604). The optical gain structures 407 may be SWCNTs, or the optical gain structures may be nanotubes, nanorods, quantum dots, quantum wells, nanoclusters, nanopowders, nanocrystals, or any combination thereof. In embodiments, the optical gain structures may be any micromaterial or nanomaterial structure capable of adsorbing into the surface of a microcavity. The optical gain structures 407 may include carbon, a semiconductor material, an inorganic semiconductor material, an organic dye, an optically nonlinear material, or a wideband insulator.

A first chemical agent is introduced to the solution to cause swelling of the microcavities in at least one spatial dimension (block 606). For example, for the PS microsphere 409 toluene is added to the solution, which causes the PS microsphere 409 to expand radially increasing the diameter of the microsphere. In examples, another polystyrene solvent may be used to cause the PS microsphere 409 to expand. For example, the first chemical agent may be chloroform, dimethylsulphoxide, or another polar organic solvent. The microsphere expands isotropically which allows for the same surface area exposure to the optical gain structures 407 over the entirety of the outer surface 402 of the microsphere 409. In other examples, such as with a planar circular microcavity, the swelling may occur substantially in the plane of the circular microcavity, and therefore may not occur isotropically. While described as using a chemical agent, swelling of the microcavity may be accelerated by providing thermal energy to the solution to heat the solution causing the microcavities to expand.

The solution is mixed using a chemical agitator during the swelling of the microcavities (block 608). The agitator may be a magnetic stir bar, magnetic stir plate, paddle agitator, helical ribbon agitator, coil impellers, hydrofoil impellers, or screw impellers. Mixing the solution causes more even distribution of the microcavities and optical gain structures throughout the solution to fabricate optical gain devices 400 having more uniform performance. The swelling of the microcavities causes attraction of the optical gain structure 407 to the outer surface 402 of the microcavities through van der Walls forces. The van der Walls attraction further causes adsorption of the optical gain structures 407 to the outer surface 402 of the microspheres 409.

A second chemical agent is then provided to the solution to cause de-swelling of the microcavities in the at least one spatial dimension of the microcavities (block 610). The second chemical agent may be ethanol, hexane, or another nonpolar organic solvent. Similarly to the swelling process, the de-swelling may occur isotropically, in a single dimension, or in two-dimensions according to the geometries of the optical gain structures 407. The de-swelling of the microcavities further strengthens the van der Walls attraction of the adsorbed optical gain structures 407 to the outer surface 402 of the microspheres 409. While described as swelling and de-swelling of the microspheres 409, in practice, only the surface 402, or a portion of the microsphere near the surface 402 may swell. Additionally, the optical gain structures 407 may have dimensions on the order of 1 nm or less in diameter and 100 nm in length. Due to the nanoscale dimensions of the optical gain structures 407, some of the optical gain structures 407 may penetrate the outer surfaces 402 of the microspheres 409 during the swelling process. The deswelling may then trap the optical gain structures 407 in the microspheres 409 near the surface 402 of the microspheres 409. Optical gain structures 407 adsorbed to, and trapped in, the surface 402 of the microsphere 409 are protected from damage by the surface 402 of the microsphere 409.

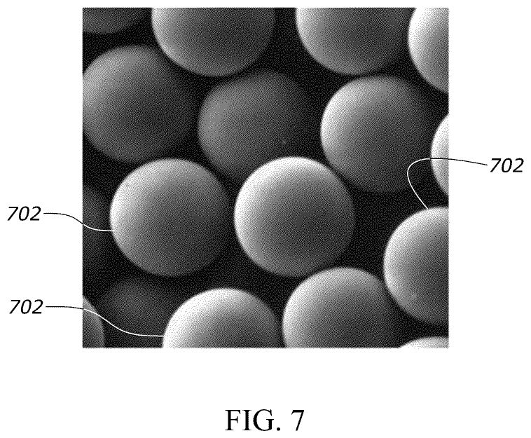

The method 600 of FIGS. 5 and 6 was performed and a plurality of optical gain devices were fabricated using microspheres as the optical cavity and SWCNTs as the optical gain structure. FIG. 7 is a microscopy image of a plurality of PS microspheres 702 used to fabricate optical gain devices as described herein. The PS microspheres 702 had diameters on the order of microns, or tens of microns. The microspheres 702 may have diameters smaller than a micron depending on a desired whispering gallery mode wavelength to support in the microsphere 702 and the refractive index of the microsphere 702.

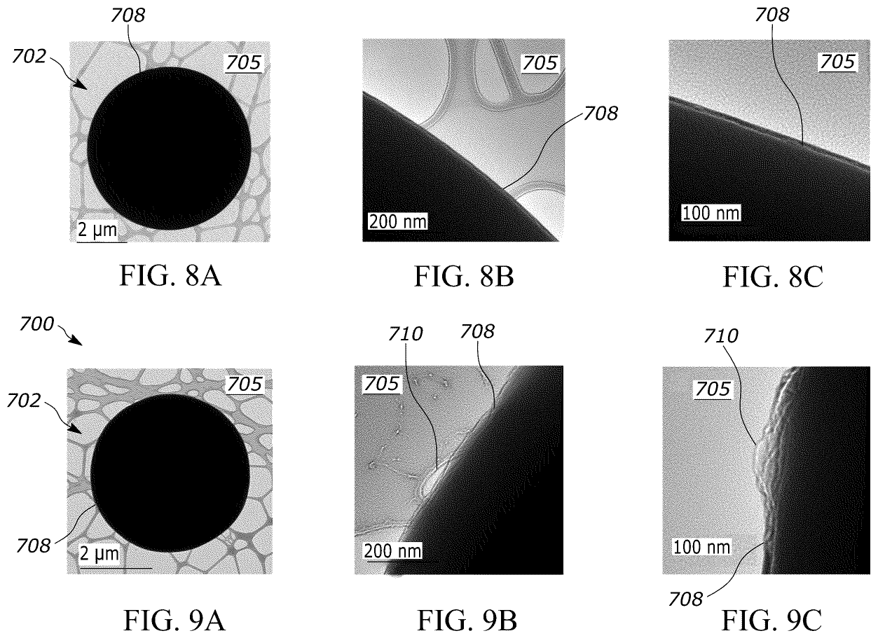

FIG. 8A-8C are microscopy images, at various magnifications, of a PS microsphere 702 spin-coated onto a lacey carbon grid 705 for fabricating an optical gain device as described herein. The microsphere 702 has a diameter of seven microns and an outer surface 708 with no nanostructures or optical gain structures disposed on or adsorbed to the outer surface 708, as shown by the smooth outer surfaces of the magnified images of FIGS. 8B and 8C. The method 600 of FIGS. 5 and 6 was performed using the PS microsphere 702 and SWCNTs 710 as the optical gain structure. FIGS. 9A-9C are microscopy images, at various magnifications, of an optical gain device 700 fabricated using the PS microsphere 702 of FIGS. 8A-8C. The optical gain device 700 has SWCNTs 710 adsorbed to the outer surface 708 of the PS microsphere 702. After the swelling/de-swelling processes were performed, the SWCNTs 710 were adsorbed to the outer surface 708 as a thin film on the outer surface 708 of the PS microsphere 702. As such, a whispering gallery mode may propagate along the outer surface 708 along any circumferential direction of the sphere 702. Any propagation of a whispering gallery mode in any direction around the sphere 702 experiences gain due to the thin film deposition of the SWCNTs 710 around the outer surface 708 of the PS microsphere 702.

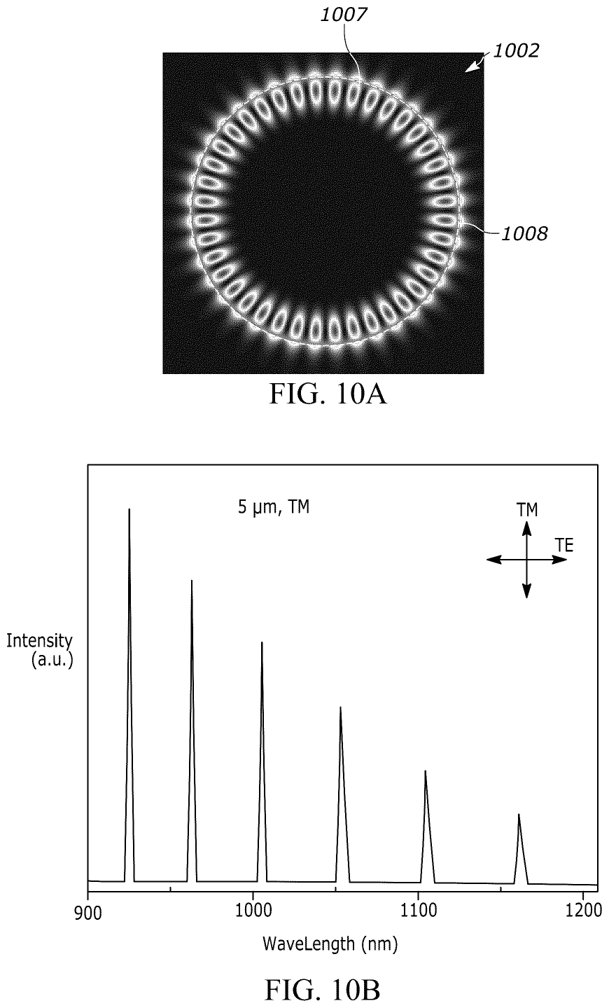

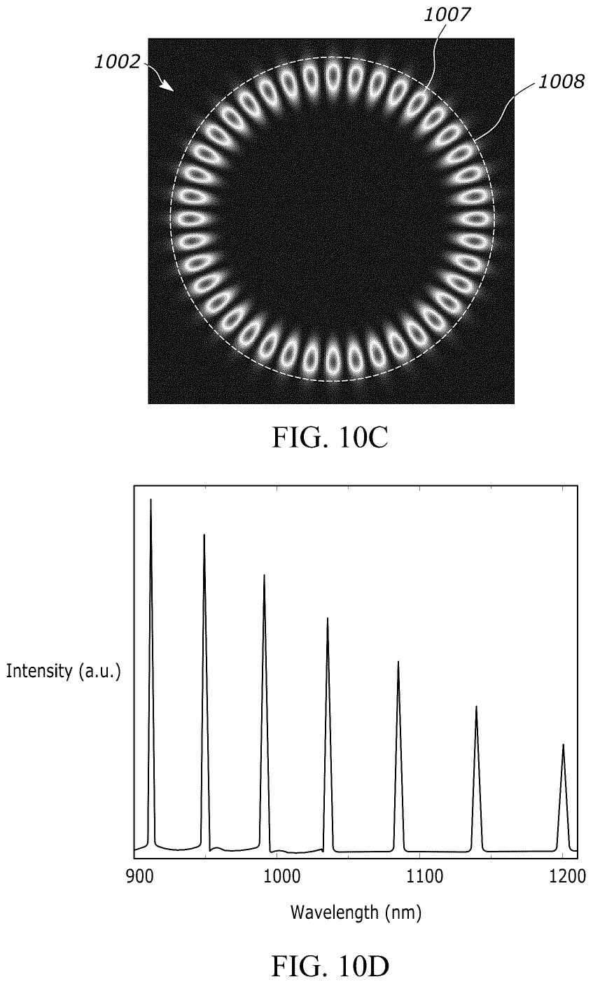

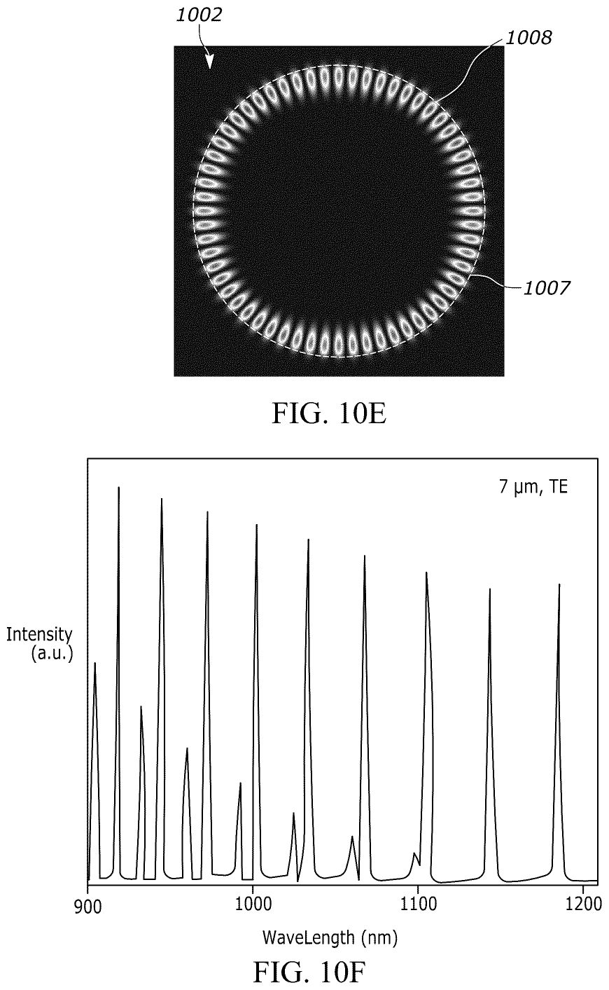

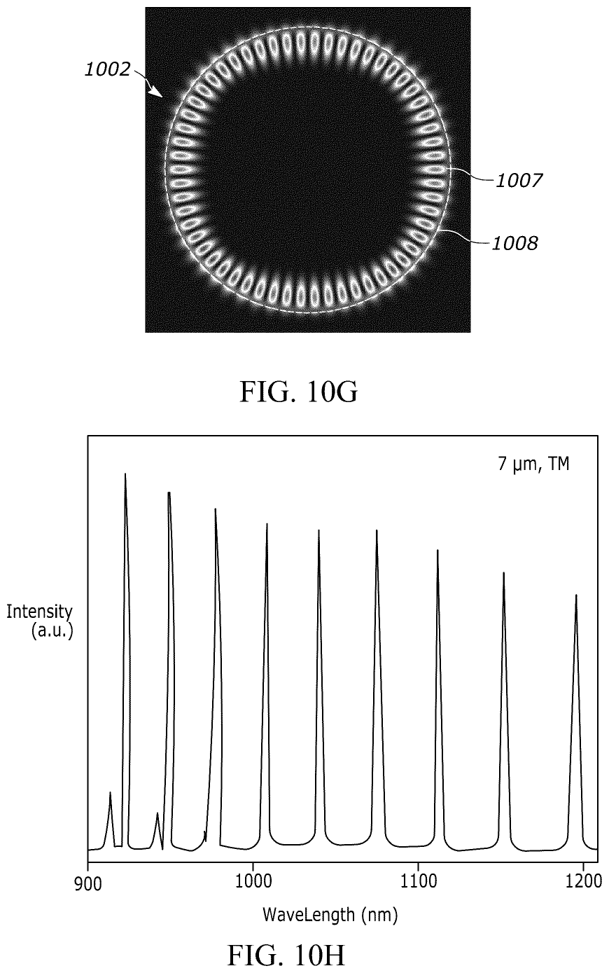

FIGS. 10A, 10C, 10E, and 10G are simulated electric field intensity distributions of transverse electric (TE), and transverse magnetic (TM) whispering gallery modes 1007 propagating along outer edges 1008 of microspheres 1002 having varied diameters. FIGS. 10B, 10D, 10F. and 10H are plots of supported whispering gallery mode wavelength spectrums for corresponding microspheres 1002 and whispering gallery modes 1007 of FIGS. 10A, 10C, 10E, and 10G respectively. FIG. 10A shows a simulation of a TM whispering gallery mode propagating in a microsphere 1002 having a five-micron diameter. The data presented in FIG. 10B shows resonant peaks at around 920 nm, 965 nm, 1010 nm, 1055 nm, 1115 nm, and 1160 nm. The resonant peaks of FIG. 10B represent the wavelengths of TM whispering gallery modes that the five micron microsphere 1002 of FIG. 10A supports. FIG. 100 is a simulation of a TE whispering gallery mode propagating in the five-micron diameter microsphere 1002. The data presented in FIG. 10D shows resonant peaks at around 910 nm, 950 nm, 990 nm, 1040 nm, 1080 nm, 1135 nm, and 1200 nm. The resonant peaks of FIG. 10D represent the wavelengths of TE whispering gallery modes that the five micron microsphere 1002 of FIG. 100 supports.

FIG. 10E is a simulation of a TE whispering gallery mode propagating in a microsphere 1002 having a seven micron diameter. The data presented in FIG. 10F shows resonant peaks of the TE mode between 900 and 1200 nm. The data of FIG. 10F shows that the microsphere 1002 supports higher order modes represented by the lower peaks near 905 nm, 935 nm, and so on. FIG. 10G shows a simulation of a TM whispering gallery mode propagating in a microsphere 1002 having a seven-micron diameter. The data presented in FIG. 10H shows resonant peaks of the TM mode between 900 and 1200 nm. As illustrated by each of FIGS. 10A, 10C, 10E, and 10G, the whispering gallery modes 1007 propagate within the microsphere 1002 with the whispering gallery modes 1007 having some spatial overlap with the outer surface 1008 of the microsphere 1002. As such, the radiation of the whispering gallery mode undergoes optical gain due to gain materials and gain structures disposed on and/or adsorbed to the outer surface 1007 of the microsphere 1002. The data presented in FIGS. 10B, 10D, 10F, and 10H shows that the wavelengths of supported whispering gallery modes is dependent on the geometries, and specifically the diameter, of a microsphere. As illustrated by FIGS. 10A-10H, the optical gain devices described herein may provide optical gain to a wide band of wavelengths depending on the geometries of the optical microcavity and chemical components of optical gain structures. As such, optical microcavities may be configured to support the propagation of whispering gallery modes having wavelengths between 700 nm and 2500 nm.

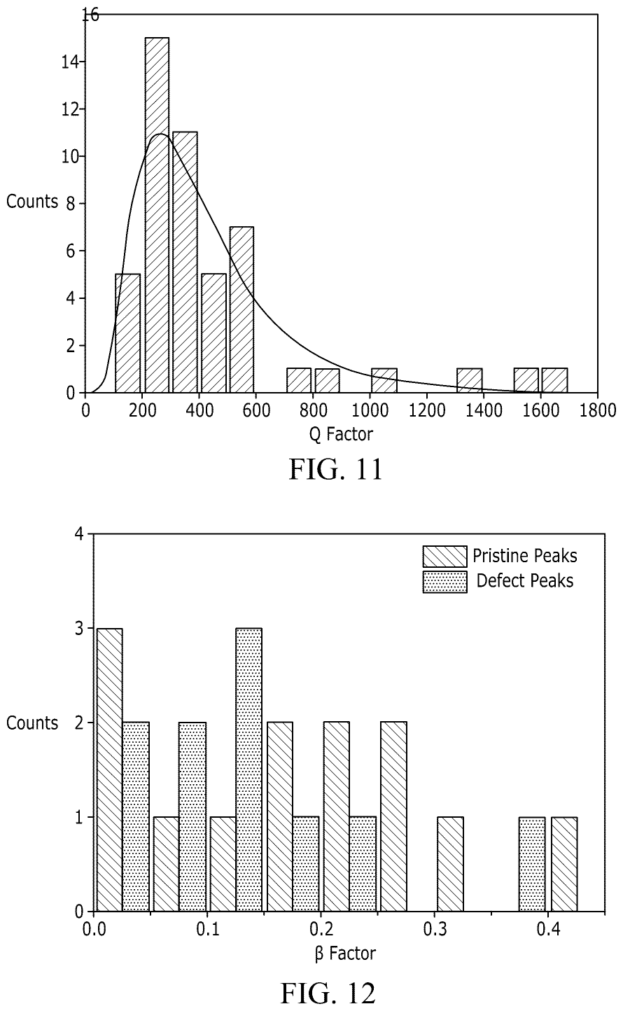

As previously discussed, a resonant cavity possessing a high quality factor allows for the amplification of more radiation which enables lasing in optical gain devices. FIG. 11 is a histogram of experimentally measured quality factors for a plurality of optical gain devices that employ PS microspheres and SWCNTs as described herein. The quality factors were measured by causing the optical gain devices to emit laser radiation, and the spectra of the emitted laser radiation was used to derived from the quality factors by

$$Q = \frac{λ}{Δ λ} , \qquad EQ . 4$$

Where Q represents the quality factor, A is a central peak wavelength of the laser radiation, and Δλ is a spectral width of the lasing spectra taken as spectral full-width at half-maximum (FWHM). The spectral width of the optical gain devices is typically on the order of a few nanometers to tens of nmanometers. The curve shown in FIG. 11 is a log-normal distribution fit to the data presented in the histogram. The average quality factor was calculated to be 396 for the plurality of optical gain devices. The quality factor could be increased to values on the order of thousands, for example between 3000 or 4000 or potentially higher by fabricating devices with high levels of surface homogeneity.

Laser output intensity is dependent on the intensity of the pump radiation provided to an optical gain medium. The pump-dependent photoluminescence (PL) intensities of the optical gain devices were investigated using a semiconductor coupled rate equation analysis method. The coupled rate equations consider both radiative and non-radiative decay processes, as well as exciton-exciton annihilation processes in SWCNTs. Beta factors, β, were derived from the coupled rate equations with β representing the amount of spontaneously emitted radiation that couples to a whispering gallery mode of the cavity. The beta factor is indicative of the amount of spontaneous emission that is coupled into the cavity. The beta factor may be used to determine how efficient an optical gain device is at using spontaneous emission to generate stimulated emission for achieving lasing. A larger beta factor value means that the system couples more spontaneous emission into the cavity, which results in lower lasing threshold powers. FIG. 12 is a histogram of beta factor values for a plurality of optical gain devices. The reported data is for PL spectral intensities with both pristine peaks and defected peaks. The pristine peaks correspond to radiation emitted from SWCNTs without a functional group, while the defect peaks are from emissions from functionalized SWCNTs. There is not a notable performance difference in the beta factor values between the functionalized, and non-functionalized SWCNTs.

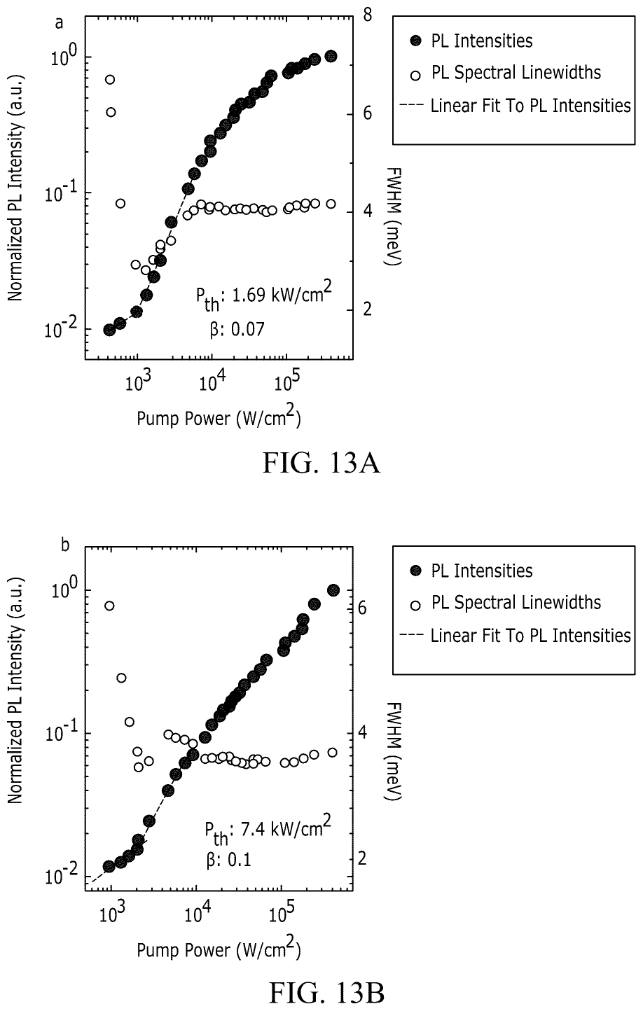

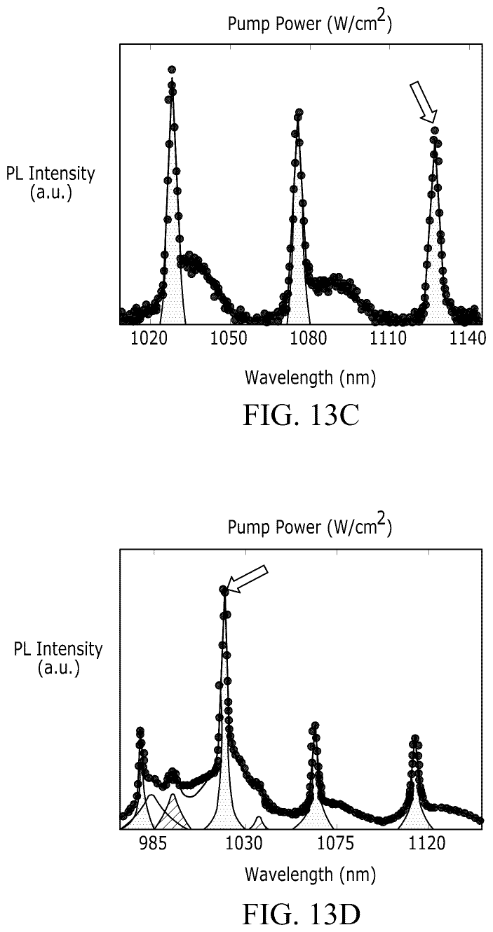

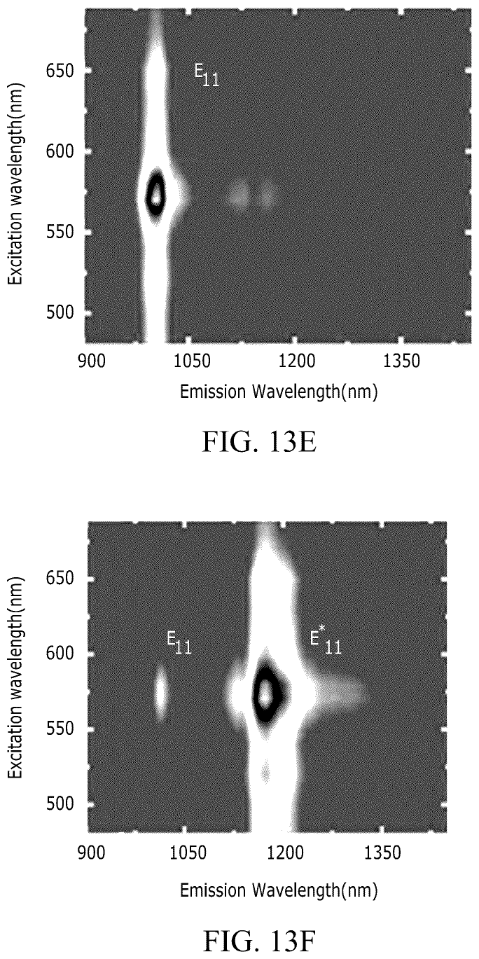

FIGS. 13A and 13B are plots of output PL laser radiation intensity versus input pump power for optical gain devices having beta factor values of 0.07 and 0.1 respectively. The lasing power for each of the optical gain devices is shown as the point at which the linear fit changes slope in each of the plots of FIGS. 13A and 13B. For example, the lasing threshold power, Pₜₕ, is around 1.68 kW/cm² for the optical gain device of FIG. 13A, and about 7.4 kW/cm² for the device of FIG. 13B. FIGS. 13C and 13D are plots of PL laser radiation spectral corresponding to the data of FIGS. 13A and 13B respectively. The spectra shown in FIGS. 13C and 13D are for the optical gain devices at the highest pump power shown in the plots of FIGS. 13A and 13B respectively. The data of FIG. 13C shows multiple local maxima with lasing wavelengths around 1030 nm, 1075 nm, and 1130 nm. The spectrum of FIG. 13B has a prominent wavelength lasing peak near 1020 nm. FIGS. 13E and 13F are plots of pump excitation wavelength vs. emission wavelength for unfunctionalized and functionalized SWCNTs respectively. The excitation wavelength was 575 nm for both scenarios of SCWNTs with and without the introduction of a functional group. The emission wavelength shifted from 1000 nm to about 1150 nm due to the introduction of the functional group. The data of FIGS. 13E and 13F shows the ability to tune the emission wavelength of a SWCNT as a gain device by introducing functional groups to the SWCNT.

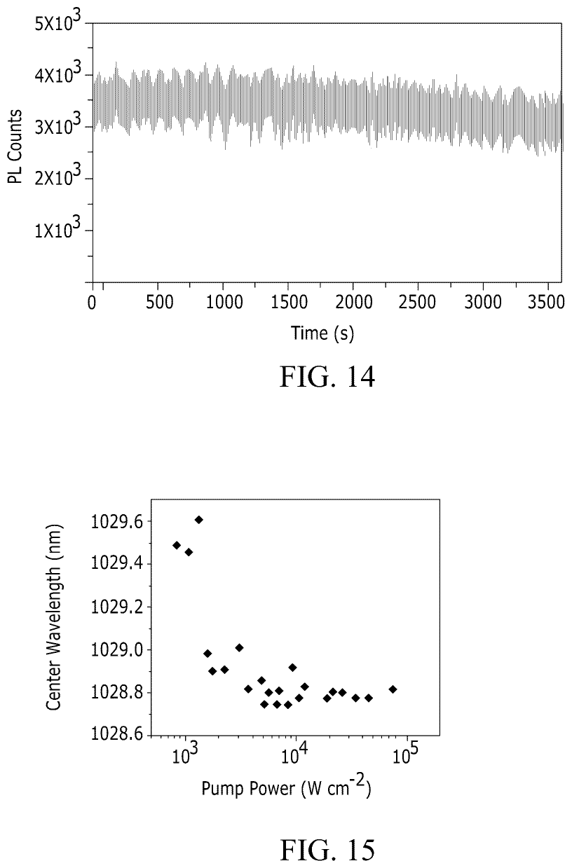

FIG. 14 is a plot of PL laser radiation intensity over time for an optical gain device employing a PS microsphere as a cavity and SWCNT as the gain structure. The output intensity reported in FIG. 14 was taken while the optical gain device was provided with pump radiation at an intensity higher that of the lasing threshold power for the device. The data of FIG. 14 shows that the optical gain device provides stable lasing over a continuous time period of nearly an hour. It is expected that stable lasing may be provided from such devices for longer times on the order of hours. FIG. 15 is a plot of peak wavelength output versus different pump powers. The data shows a blue-shift of 0.8 nm as the pump power is increased above the lasing threshold. No other apparent blue- or red-shifts were observed once lasing was achieved. The data presented in FIGS. 14 and 15 illustrates the output power stability, and stable wavelength performance of the disclosed optical gain devices during lasing.

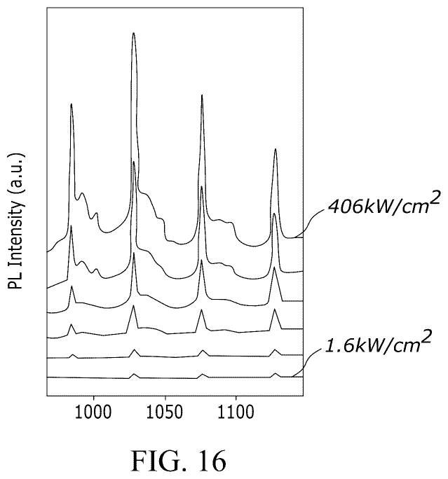

FIG. 16 is a plot of photoluminescent (PL) laser radiation intensity spectra for different pump powers provided to non-functionalized SWCNTs coupled as a gain medium to PS microspheres. The data of FIG. 16 shows PL emission peaks near 1030 nm, 1075 nm, and 1130 nm with increased output intensity as the pump power is increased from 1.6 kW/cm² to 406 kW/cm². The quality factors of the microsphere optical gain structures may then be determined from the spectral peaks of FIG. 16 taking the central wavelengths and FWHM bandwidths of the spectral peaks as described by EQ. 4.

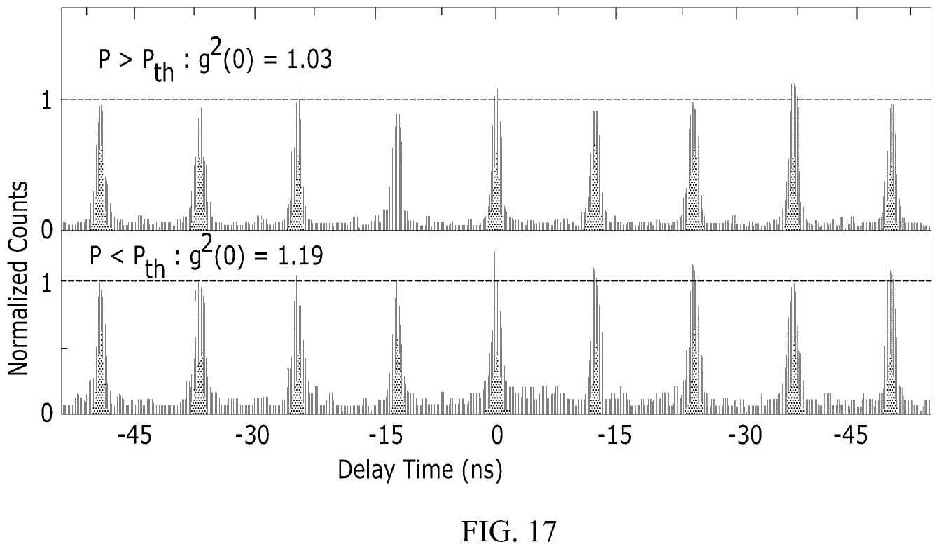

FIG. 17 shows two plots of normalized output PL photon count at pump powers greater than (top), and less than (bottom) the lasing threshold power of an optical gain device as described herein. The statistics of the output PL photon count results in a second-order correlation coefficient, g², of greater than one at pump powers below the lasing threshold, and values of nearly one at powers greater than the lasing threshold. A g² value of one indicates that the device is outputting photons according to a Poissonian distribution, which is another indication of lasing from an optical gain device or optical gain medium.

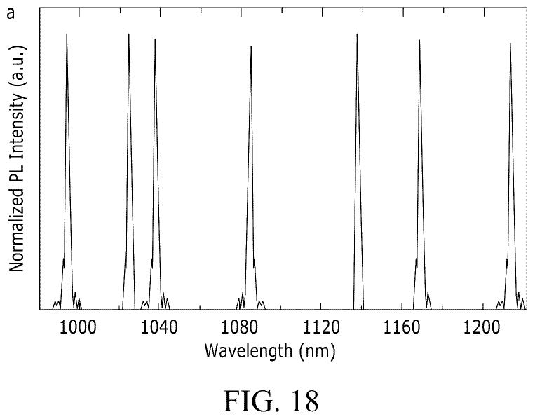

FIG. 18 is a plot of PL lasing spectra for optical gain devices having different microsphere diameters and different SWCNT chemical modifications (e.g., different functional groups). The spectra of FIG. 18 show that the optical gain devices may be tuned to provide laser radiation across a band from 1 micron to longer than 1.2 microns. The lasing spectra of FIG. 18 were all generated by SWCNTs with a diameter of approximately 0.8 nm. The peak near 992 nm are from non-functionalized (without additional functional groups), and the peaks near 1022 nm, 1036 nm, 1084 nm, 1137 nm are from functionalized SWCNTs adsorbed to 5 um diameter microspheres. The peaks near 1166 nm and 1213 nm are from 4-nitrobenzene functionalized SWCNTs adsorbed with 7 um microspheres. In examples, the diameters and chemical properties of the optical gain devices may be designed to tune the laser radiation output spectrum to have wavelengths from 700 nm to 2500 nm, and therefore, the optically active wavelength ranges of the optical gain structures may be tuned from 800 nm to 2500 nm. In embodiments, the laser radiation output spectrum may be in the range of 950 nm to 1300 nm, or extended into the IR range from 800 nm to 1600 nm.

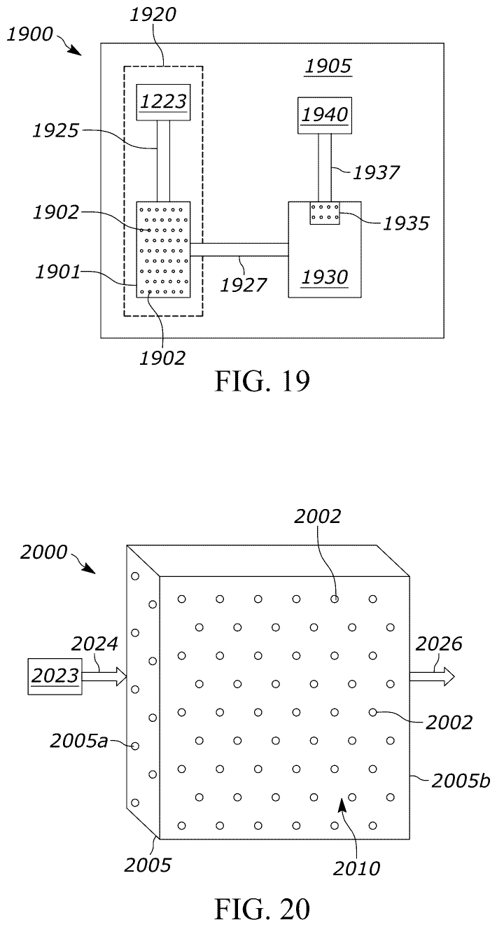

The optical gain devices described herein may be implemented in fabricating lasing devices of various form factors and sizes. As previously described, the miniaturization of lasers for implementing as on-chip light sources has been challenging due to temperature control requirements, the inability of miniaturized gain structures to emit in the NIR and IR range, and due the bulky sizes of current IR laser gain technologies. The described optical gain devices provide a small form factor device capable of lasing at room temperature. FIG. 19 is a block diagram illustrating an example of an optical processing system 1900 having an on-chip lasing device 1920 that provides laser radiation to the optical processing system 1900. The optical processing system 1900 may be a quantum computing device, a neuromorphic computing device, or a conventional processor. The optical processing system 1900 may include optical interconnects for transmitting optical signals between components of the optical processing system 1900. The on-chip lasing device 1920 includes a gain region 1901 having a plurality of optical gain devices 1902 disposed on a substrate 1905 in the gain region 1901. Each of the optical gain devices 1902 includes a resonant cavity (e.g., microsphere, microdisk, etc.) and optical gain structures (e.g., nanorods, SWCNTs, etc.) adsorbed to an outer surface of the resonant cavity. The optical gain devices 1902 may be deposited on the substrate 1905 using microfabrication techniques such as by micromanipulators.

The on-chip lasing device 1920 further includes a pump source 1923 that provides pump radiation to a pump waveguide 1925. The pump waveguide 1925 guides the pump radiation to the gain region 1901 and the pump radiation causes stimulated emission from the optical gain devices 1902 resulting in the emission of laser radiation. A bus waveguide 1927 guides the laser radiation from the on-chip lasing device 1920 to other components of the optical processing system 1900. For example, the bus waveguide 1927 may guide the laser radiation to an optical processing unit 1930 which may perform processing operations on the laser radiation. The optical processing unit 1930 may further include a secondary on-chip lasing device 1935 and the optical processing unit 1930 may provide radiation to the secondary on-chip lasing device 1935 to generate laser radiation from the secondary on-chip lasing device 1935. The secondary on-chip lasing device 1935 may contain a plurality of optical gain devices as described herein for generating laser radiation. A storage bus waveguide 1937 may guide the laser radiation from the secondary on-chip lasing device 1935 to a memory 1940 to store information in the memory 1940. The memory 1940 may include one or more semiconductor transistors for storing electrical bits, or the memory 1940 may include optical quantum memory that stores qubits and quantum states of photons. The optical processing system 1900 may include other components for performing optical processing such as polarizers, waveplates, beam splitters, etc. Additionally, the optical processing system 1900 may have different waveguide geometries and optical paths for propagating radiation between on-chip components, or to provide radiation to external and off-chip devices.

FIG. 20 is a diagram of a lasing device 2000 that includes a plurality of optical gain devices 2002 dispersed in a fluid solution 2010. A rectangular cuvette 2005 contains both the solution 2010 and the plurality of optical gain devices 2002. A pump source 2023 provides pump radiation 2024 to the optical gain devices 2002 through a first surface 2005a of the cuvette 2005. The pump radiation 2023 excites optical gain structures of the optical gain devices 2002 resulting in stimulated emission of laser radiation 2026 from the optical gain devices 2002. The laser radiation 2026 then exits the cuvette 2005 through a second surface 2005b of the cuvette 2005.

In embodiments, the optical gain devices 2002 may be disposed in a fluid that is not contained in a cuvette. For example, in biological applications, the optical gain devices 2002 may be injected into a patient in a region near an organ or other tissue. Pump radiation may be provided to the region containing the optical gain devices 2002 to cause the emission of laser radiation from the optical gain devices 2002. In such applications, the laser radiation may be emitted isotropically from the plurality of optical gain devices 2002 into nearby tissue.

The following list of aspects reflects a variety of the embodiments explicitly contemplated by the present disclosure. Those of ordinary skill in the art will readily appreciate that the aspects below are neither limiting of the embodiments disclosed herein, nor exhaustive of all of the embodiments conceivable from the disclosure above, but are instead meant to be exemplary in nature.

1. An optical gain device comprising: an optical microcavity having a refractive index and a curvilinear outer surface with an angle of curvature such that the optical microcavity supports the propagation of an electromagnetic whispering gallery mode; and a plurality of optical gain structures disposed along the curvilinear outer surface of the optical microcavity, the each of the optical gain structures having an optically active wavelength range over which each of the corresponding optical gain structures provides optical gain to radiation through stimulated emission.

2. The device according to aspect 1, wherein the optical microcavity comprises a microsphere.

3. The device according to either of aspect 1 or 2, wherein the electromagnetic whispering gallery mode has a wavelength between 700 nm and 2500 nm.

4. The device according to any of aspects 1 to 3, wherein the plurality of optical gain structures comprises a nanotube, a nanorod, a quantum dot, a quantum well, a nanocluster, a nanopowder, a nanocrystal, or any combination thereof.

5. The device according to any of aspects 1 to 3, wherein the plurality of optical gain structures comprises a single-walled carbon nanotube.

6. The device according to any of aspects 1 to 4, wherein the plurality of optical gain structures comprises a semiconductor material.

7. The device according to any of aspects 1 to 6, wherein the optically active wavelength range comprises wavelengths of between 700 nm and 2500 nm.

8. A lasing device comprising: a plurality of optical gain devices according to any of aspects 1 to 7, the plurality of optical gain devices disposed on a substrate; and a pump radiation source configured to provide pump radiation to the plurality of optical gain devices, the pump radiation having an energy capable of inducing stimulated emission from the gain material.

9. A lasing device comprising: a plurality of optical gain devices according to any of aspects 1 to 7, with the plurality of optical gain devices suspended in a solution; and a pump radiation source configured to provide pump radiation to the plurality of optical gain devices, the pump radiation having an energy capable of inducing stimulated emission from the gain material.

10. A method comprising: fabricating a plurality of optical gain devices according to aspect 1 by: providing a plurality of optical microcavities to a solution; providing a plurality of optical gain structures to the solution; causing swelling of the plurality of optical microcavities to increase at least one spatial dimension of the optical microcavities while in the presence of the optical gain structure; and causing de-swelling of the optical microcavities to reduce the at least one spatial dimension of the optical microcavities to adsorb the at least a portion of optical gain structures to the outer surface of the optical microcavities.

11. The method of aspect 10, wherein causing swelling of the optical microcavities comprises providing a chemical agent to the solution to induce swelling of the optical microcavities.

12. The method of aspect 10, wherein causing swelling of the optical microcavities comprises providing thermal energy to the optical microcavities to heat the optical microcavities.

13. The method according to any of aspects 10 to 12, wherein causing de-swelling of the optical microcavities comprises providing a chemical agent to the solution to induce de-swelling of the optical microcavities.

14. The method according to any of aspects 10 to 12, wherein causing de-swelling of the optical microcavities comprises providing thermal cooling to the optical microcavities to reduce the temperature of the optical microcavities.

15. The method according to any of aspects 10 to 14, further comprising mixing the solution while causing the swelling and the de-swelling of the plurality of optical microcavities to distribute the optical microcavities and the optical gain structures throughout the solution.

15. The method according to any of aspects 10 to 15, wherein providing the plurality of optical microcavities to the solution comprises providing a plurality of microspheres to the solution.

16. The method according to any of aspects 10 to 15, wherein providing the plurality of optical gain structures to the solution comprises a nanotube, a nanorod, a quantum dot, a quantum well, a nanocluster, a nanopowder, a nanocrystal, or any combination thereof, to the solution.

17. The method according to any of aspects 10 to 16, wherein providing the plurality of optical gain structures to the solution comprises providing a semiconductor material to the solution.

18. The method of according to any of aspects 10 to 15, wherein providing the plurality of optical gain structures to the solution comprises providing a single walled carbon nanotube to the solution.

18. A method of achieving optical gain, the method comprising: providing pump radiation to an optical gain device, the optical gain device including (i) an optical microcavity having a refractive index and an outer perimeter, with the outer perimeter having a perimeter geometry, and (ii) a gain material disposed along the outer perimeter of the optical microcavity, the gain material having an optically active wavelength range, the optically active wavelength range being a range of wavelengths over which the optical microcavity provides optical gain through stimulated emission.

20. The method of aspect 19, wherein the optical microcavity comprises a microsphere.

21. The method according to either of aspect 19 or 20, wherein the refractive index and the perimeter geometry are selected to support the propagation of an electromagnetic whispering gallery mode.

22. The method according to aspect 21, wherein the electromagnetic whispering gallery mode has a wavelength between 700 nm and 2500 nm.

23. The method according to any of aspects 19 to 22, wherein the gain material comprises a nanotube, a nanorod, a quantum dot, a quantum well, a nanocluster, a nanopowder, a nanocrystal, or any combination thereof.

24. The method according to any of aspects 19 to 22, wherein the gain material comprises a single-walled carbon nanotube.

25. The method according to any of aspects 19 to 22, wherein the gain material comprises a semiconductor material.

26. The method of according to any of aspects 19 to 25, wherein the optically active wavelength range comprises wavelengths of between 700 nm and 2500 nm.

What is claimed is:

1. An optical gain device comprising:
an optical microcavity having a refractive index and a curvilinear outer surface with an angle of curvature such that the optical microcavity supports the propagation of an electromagnetic whispering gallery mode; and
a plurality of optical gain structures disposed along the curvilinear outer surface of the optical microcavity, the each of the optical gain structures having an optically active wavelength range-over which each of the corresponding optical gain structures provides optical gain to radiation through stimulated emission.

2. The device of claim 1, wherein the optical microcavity comprises a microsphere.

3. The device of claim 1, wherein the electromagnetic whispering gallery mode has a wavelength between 700 nm and 2500 nm.

4. The device of claim 1, wherein the plurality of optical gain structures comprises a nanotube, a nanorod, a quantum dot, a quantum well, a nanocluster, a nanopowder, a nanocrystal, or any combination thereof.

5. The device of claim 1, wherein the plurality of optical gain structures comprises a single-walled carbon nanotube.

6. The device of claim 1, wherein the plurality of optical gain structures comprises a semiconductor material.

7. The device of claim 1, wherein the plurality of optical gain structures are adsorbed to the curvilinear outer surface of the optical microcavity.

8. The device of claim 1, wherein the optically active wavelength range comprises wavelengths of between 700 nm and 2500 nm.

9. A lasing device comprising:
a plurality of optical gain devices according to claim 1, the plurality of optical gain devices disposed on a substrate; and
a pump radiation source configured to provide pump radiation to the plurality of optical gain devices, the pump radiation having an energy capable of inducing stimulated emission from the gain material.

10. A lasing device comprising:
a plurality of optical gain devices according to claim 1, with the plurality of optical gain devices suspended in a solution; and
a pump radiation source configured to provide pump radiation to the plurality of optical gain devices, the pump radiation having an energy capable of inducing stimulated emission from the gain material.

11. A method comprising:
fabricating a plurality of optical gain devices according to claim 1 by:
providing a plurality of optical microcavities to a solution;
providing a plurality of optical gain structures to the solution;
causing swelling of the plurality of optical microcavities to increase at least one spatial dimension of the optical microcavities while in the presence of the optical gain structures; and
causing de-swelling of the optical microcavities to reduce the at least one spatial dimension of the optical microcavities to adsorb at least a portion of optical gain structures to the outer surface of the optical microcavities.

12. The method of claim 11, wherein causing swelling of the optical microcavities comprises providing a chemical agent to the solution to induce swelling of the optical microcavities.

13. The method of claim 11, wherein causing de-swelling of the optical microcavities comprises providing a chemical agent to the solution to induce de-swelling of the optical microcavities.

14. The method of claim 11, further comprising mixing the solution while causing the swelling and the de-swelling of the plurality of optical microcavities to distribute the optical microcavities and the optical gain structures throughout the solution.

15. The method of claim 11, wherein providing the plurality of optical microcavities to the solution comprises providing a plurality of microspheres to the solution.

16. The method of claim 11, wherein providing the plurality of optical gain structures to the solution comprises providing a nanotube, a nanorod, a quantum dot, a quantum well, a nanocluster, a nanopowder, a nanocrystal, or any combination thereof, to the solution.

17. The method of claim 11, wherein providing the plurality of optical gain structures to the solution comprises providing a semiconductor material to the solution.

18. The method of claim 11, wherein providing the plurality of optical gain structures to the solution comprises providing a single walled carbon nanotube to the solution.
